(19) United States
(12) Patent Application Publication
(10) Pub. No.: US 2018/0102315 A1
(43) Pub. Date: Apr. 12, 2018

(54) SURFACE AREA-DEPENDENT SEMICONDUCTOR DEVICE WITH INCREASED SURFACE AREA

(71) Applicant: GLOBALFOUNDRIES Inc., Grand Cayman (KY)

(72) Inventors: Roderick Alan AUGUR, Rhinebeck, NY (US); Roger A. QUON, Albany, NY (US); Shawn P. FETTEROLF, Cornwall, VT (US)

(73) Assignee: GLOBALFOUNDRIES Inc., Grand Cayman (KY)

(21) Appl. No.: 15/290,907

(22) Filed: Oct. 11, 2016

(51) Int. Cl. H01L 23/522; H01L 21/311; H01L 49/02; H01L 21/768; H01L 23/528

(52) U.S. Cl. CPC H01L 23/5223; H01L 21/311; H01L 23/528; H01L 21/76816; H01L 28/60

(57) ABSTRACT

The surface area of a surface area-dependent semiconductor device is increased by providing a dielectric layer, removing portion(s) of the dielectric layer, resulting in recession(s), and forming surface area-dependent semiconductor device(s), a portion of the device being formed along a sidewall of one, or more, of the recession(s). The resulting semiconductor structure includes a dielectric layer having recession(s) therein, and surface area-dependent semiconductor device(s) having a portion thereof formed along a sidewall of the recession(s).

### BACKGROUND OF THE INVENTION

### Technical Field

The present invention generally relates to surface area-dependent semiconductor devices. More particularly, the present invention relates to increasing the surface area of surface area-dependent semiconductor devices.

### Background Information

As the size of semiconductor devices continues to shrink, maximizing a surface area-dependent device characteristic becomes more and more challenging, particularly with concurrent demand for reduced fabrication costs and increased capacitance density per unit footprint. Thus, the design of such semiconductor devices must increase the surface area, ideally, without increasing a footprint of the device. For example, metal-insulator-metal capacitors (MIMCAPs) used for interconnect structures depend on surface area to maximize capacitance. Solutions for MIMCAPs suffer limited capacitance density, reliability concerns and/or complicate the device design. In addition to continued down-scaling, the industry faces a demand for reduced fabrication costs and increased capacitance density per unit footprint.

Thus, a need continues to exist for increasing the area of an area-dependent semiconductor device while minimizing or avoiding an increased footprint.

### SUMMARY OF THE INVENTION

The shortcomings of the prior art are overcome and additional advantages are provided through the provision, in one aspect, of a method of increasing the surface area of a surface area-dependent semiconductor device. The method includes providing a dielectric layer, removing at least one portion of the dielectric layer, resulting in one or more recessions, and forming at least one surface area-dependent semiconductor device, a portion of the device being formed along a sidewall of one of the one or more recessions.

In accordance with another aspect, a semiconductor structure is provided. The semiconductor structure includes a dielectric layer having one or more recessions therein, and at least one surface area-dependent semiconductor device having a portion thereof situated along a sidewall of the one or more recessions.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a top-down view of one example of a semiconductor structure, the structure including a dielectric layer with a planar surface, and a number of recessions having a circular shape and being arranged in a honeycomb-like pattern, there being a minimum width dielectric wall between the recessions, each recession having a radius and a pitch from center to center of adjacent circular recessions, in accordance with one or more aspects of the present invention.

FIG. 2 is a side view of one example of a recession from FIG. 1, with a surface area-dependent semiconductor device (in this example, a two-plate metal-insulator-metal capacitor (MIMCAP)) having a portion thereof formed along a vertical sidewall of the recession, in accordance with one or more aspects of the present invention.

FIG. 3 is a top-down view of one example of a semiconductor structure similar to FIG. 1, except that a cross-sectional shape of the recessions is a regular hexagon, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus ten percent of the value. Also, unless otherwise specified, a given aspect of semiconductor fabrication described herein may be accomplished using conventional processes and techniques, where part of a method, and may include conventional materials appropriate for the circumstances, where a semiconductor structure is described.

Reference is made below to the drawings, which are not drawn to scale for ease of understanding, wherein the same reference numbers are used throughout different figures to designate the same or similar components.

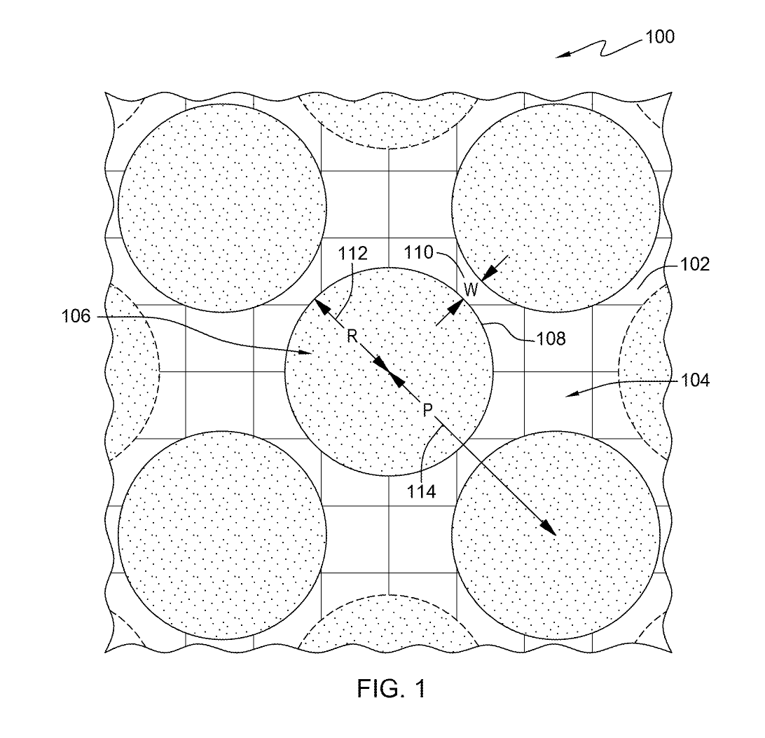

FIG. 1 is a top-down view of one example of a semiconductor structure 100, the structure including a dielectric layer 102 with a planar surface 104, and a number of recessions or depressions (e.g., via 106) having a circular shape and being arranged in a honeycomb-like pattern, there being a minimum width 108 dielectric wall (e.g., dielectric wall 110) between the recessions, each recession having a radius (e.g., radius 112) and a pitch 114 from center to center of adjacent circular recessions, in accordance with one or more aspects of the present invention.

The semiconductor structure of FIG. 1 may be conventionally fabricated, for example, using known processes and techniques. Further, unless noted otherwise, conventional processes and techniques may be used to achieve individual steps of the fabrication process of the present invention. However, although only a portion is shown for simplicity, it will be understood that, in practice, many such structures are typically included, for example, in an interconnect structure for one or more semiconductor devices.

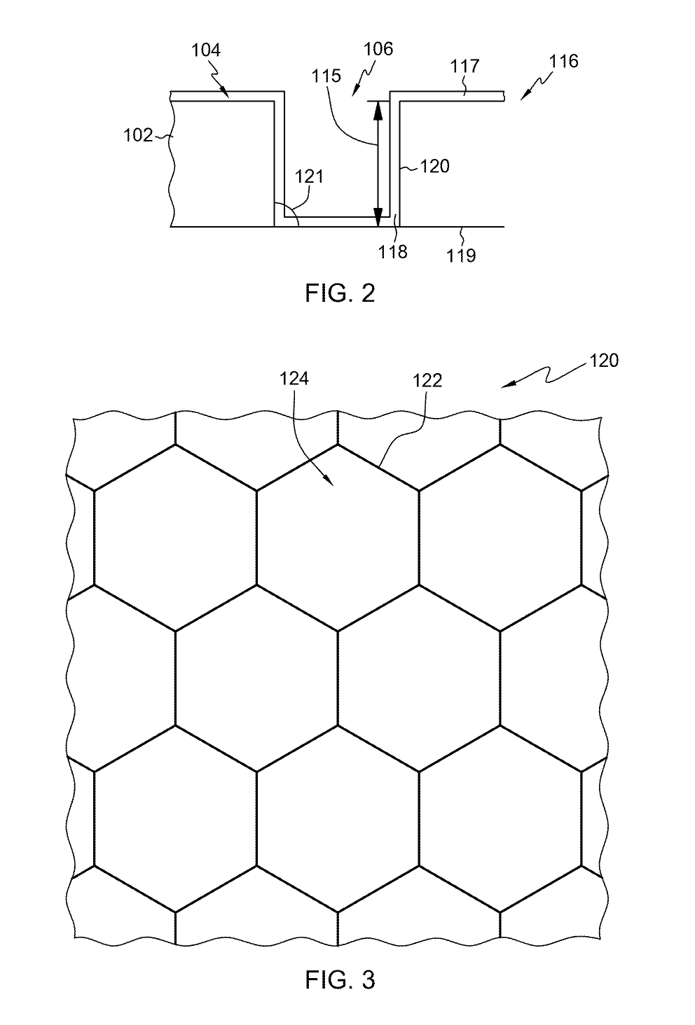

FIG. 2 is a side view of one simplified example of a recession 106 from FIG. 1, with a surface area-dependent semiconductor device 116 (in this example, a two-plate 117, 119 metal-insulator-metal capacitor (MIMCAP)) having a portion 118 thereof formed along a vertical or near vertical sidewall 120 of the recession, the sidewall having a sidewall angle 121, in accordance with one or more aspects of the present invention.

As can be seen in FIG. 2, a surface area of MIMCAP 116 is increased by a length 115 of portion 118. The increased length increases the capacitor density without increasing a footprint of the capacitor in the structure. The recessions (e.g., 106) may be formed, for example, by removing circular portions of dielectric layer 102. The removal may be accomplished using, for example, conventional etch processes and techniques. In addition, the angle 121 of the sidewalls should ideally be as close to 90 degrees (perfectly vertical) as possible. The MIMCAP may be formed using, for example, physical vapor deposition.

FIG. 3 is a top-down view of one example of a semiconductor structure 120 similar to FIG. 1, including a vertical or near vertical sidewall 122, except that a shape of the recession is a regular hexagon (e.g., hexagon-shaped recession 124), in accordance with one or more aspects of the present invention.

Theoretically, a regular hexagon shape in a honeycomb pattern would maximize the capacitance, because it enables the minimum width 110 dielectric wall to be used at all locations, and thereby maximizing the total length of vertical sidewall. However, in the current state of semiconductor fabrication, the regular hexagon shape may be difficult to achieve. For example, patterning using lithography would be challenging, though far from impossible. Theoretically, other and arbitrary shapes of recession may be used (in additional to, or instead of, circles and hexagons).

In a first aspect, disclosed above is a method. The method includes providing a dielectric layer, removing portion(s) of the dielectric layer, resulting in recessions(s), and forming surface area-dependent semiconductor device(s), a portion of each device being formed along a sidewall of one, or more, of the recessions(s).

In one example, the dielectric layer may be, for example, part of a semiconductor interconnect structure for semiconductor device(s), and the surface area-dependent semiconductor device(s) may include, for example, metal-insulator-metal (MIM) capacitor(s) having at least two plates. In one example, the at least two plates may include, for example, at least three plates.

In one example, the dielectric layer in the method of the first aspect may be, for example, part of a semiconductor interconnect structure for semiconductor device(s), and the surface area-dependent semiconductor device(s) may include environmental sensor(s).

In one example, the recession(s) in the method of the first aspect may have, for example, a regular hexagonal shape. In one example, the recessions(s) may include, for example, a regular hexagonal shape arranged in a honeycomb pattern.

In one example, the recession(s) in the method of the first aspect may have, for example, a circular shape. In one example, the recession(s) may include, for example, a circular shaped cross-section arranged in a honeycomb pattern.

In one example, the recession(s) may include, for example, recessions with a circular shaped cross-section arranged in an arbitrary pattern.

In one example, the removing in the method of the first aspect may include, for example, patterning the dielectric layer.

In a second aspect, disclosed above is a semiconductor structure. The semiconductor structure includes a dielectric layer having recession(s) therein, and surface area-dependent semiconductor device(s) having a portion thereof formed along a sidewall of the recession(s).

In one example, the dielectric layer may be, for example, part of a semiconductor interconnect structure for semiconductor device(s), and the surface area-dependent semiconductor device(s) may include, for example, metal-insulator-metal (MIM) capacitor(s) having at least two plates. In one example, the at least two plates may include, for example, at least three plates.

In one example, the dielectric layer of the semiconductor structure of the second aspect may be, for example, part of a semiconductor interconnect structure for semiconductor device(s), and the surface area-dependent semiconductor device may include environmental sensor(s).

In one example, the recession(s) of the semiconductor structure of the second aspect may have, for example, a regular hexagonal shape. In one example, the recession(s) may include, for example, multiple regular hexagonal shapes arranged in a honeycomb pattern.

In one example, the recession(s) of the semiconductor structure of the first aspect may have, for example, a circular shape. In one example, the recession(s) may include, for example, multiple circular shapes arranged in a honeycomb pattern.

In one example, the recession(s) may include, for example, recessions with a circular shaped cross-section arranged in an arbitrary pattern.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a dielectric layer;
removing at least one portion of the dielectric layer, resulting in one or more recessions;
forming at least one surface area-dependent semiconductor device, a portion of the device being formed along a sidewall of one of the one or more recessions;
wherein at least one of the one or more recessions has a regular hexagonal shaped cross-section; and
wherein the at least one of the one or more recessions comprises a plurality of recessions with a regular hexagonal shaped cross-section arranged in a honeycomb pattern, wherein adjacent recessions share a sidewall, and wherein the sidewall has a minimum width.

2. The method of claim 1, wherein the dielectric layer is part of a semiconductor interconnect structure for one or more semiconductor devices, and wherein the at least one surface area-dependent semiconductor device comprises at least one metal-insulator-metal (MIM) capacitor having at least two plates.

3. The method of claim 2, wherein the at least two plates comprise at least three plates.

4. The method of claim 1, wherein the dielectric layer is part of a semiconductor interconnect structure for one or more semiconductor devices, and wherein the at least one surface area-dependent semiconductor device comprises at least one environmental sensor.

5-9. (canceled)

10. The method of claim 1, wherein the removing comprises patterning the dielectric layer.

11. A semiconductor structure, comprising:
a dielectric layer having one or more recessions therein;
at least one surface area-dependent semiconductor device having a portion thereof formed along a sidewall of the one or more recessions;
wherein at least one of the one or more recessions has a regular hexagonal shaped cross-section; and
wherein the at least one of the one or more recessions comprises a plurality of recessions with a regular hexagonal shaped cross-section arranged in a honeycomb pattern, and wherein adjacent recessions share a sidewall having a minimum width.

12. The semiconductor structure of claim 11, wherein the dielectric layer is part of a semiconductor interconnect structure for one or more semiconductor devices, and wherein the at least one surface area-dependent semiconductor device comprises at least one metal-insulator-metal (MIM) capacitor having at least two plates.

13. The semiconductor structure of claim 12, wherein the at least two plates comprise at least three plates.

14. The semiconductor structure of claim 11, wherein the dielectric layer is part of a semiconductor interconnect structure for one or more semiconductor devices, and wherein the at least one surface area-dependent semiconductor device comprises at least one environmental sensor.

15-19. (canceled)
